(19) United States
(12) Patent Application Publication
(10) Pub. No.: US 2004/0012940 A1
(43) Pub. Date: Jan. 22, 2004

(54) Fault-tolerant assembly of printed circuit board

(76) Inventors: David K.J. Kim, San Jose, CA (US); Robert Alden Cook, San Francisco, CA (US)

Correspondence Address: Brian M. Berliner, Esq., O'MELVENY & MYERS LLP, 400 South Hope Street, Los Angeles, CA, 90071-2899, US

(21) Appl. No.: 09/788,867

(22) Filed: Feb. 20, 2001

(51) Int. Cl. H05K 7/14; H05K 7/18

(52) U.S. Cl. 361/801

(57) ABSTRACT

The present invention provides a method and apparatus for fault-tolerant assembly of printed circuit board. In one embodiment of the present invention, an EMI gasket is configured to attach to a mounting bracket by snapping into place. Once attached, the EMI gasket is able to move some distance in every direction. Thus, this embodiment provides greater fault tolerance in PCB assembly. In one embodiment, the slot for the screw used to affix the PCB to the system is elongated. In this embodiment, the elongation of the slot allows the PCB to move some distance in line with the PCB. Thus, the embodiment provides greater fault tolerance in PCB assembly and PCBs are no longer munseated by screwing the mounting bracket to the system. In another embodiment, the slot is enclosed. In this embodiment, the mounting bracket cannot slip free of the screw.

### BACKGROUND OF THE INVENTION

1. Field of the Invention

The present invention relates to the field of printed circuits boards, and in particular to a method and apparatus for fault-tolerant assembly of printed circuit boards.

Sun, Sun Microsystems, the Sun logo, Solaris and all Java-based trademarks and logos are trademarks or registered trademarks of Sun Microsystems, Inc. in the United States and other countries. All SPARC trademarks are used under license and are trademarks of SPARC International, Inc. in the United States and other countries. Products bearing SPARC trademarks are based upon an architecture developed by Sun Microsystems, Inc.

2. Background Art

Typically, during the manufacture of printed circuit boards (PCB), an electromagnetic interference (EMI) gasket is attached to a mounting bracket (e.g., a peripheral component interconnect (PCI) bracket). The mounting bracket affixes a PCB to a location in an electronic system. However, if the mounting bracket is not properly attached to the PCB, it does not form a complete coupling between the electronic connectors of the PCB and the electronic system. Prior art methods are insufficient and inefficient for attaching the mounting bracket to the PCB. This problem can be better understood by a review of PCB assembly.

PCB Assembly

A PCB is typically attached to a mounting bracket assembly comprised of a PCI bracket and an EMI gasket. Some prior art methods attach an EMI gasket to a PCI bracket by spot-welding the EMI gasket to the PCI bracket. Spot-welding does not allow the EMI gasket to move once it is attached to the PCI bracket, so a mounting bracket assembly where the EMI gasket is spot-welded to the PCI bracket has a low fault-tolerance. Thus, if the EMI gasket is mis-aligned as it is spot-welded to the PCI bracket, the mounting bracket assembly will not function correctly and the entire assembly must be discarded.

Some prior art methods mechanically bend tabs on the EMI gasket around the PCI bracket to hold the gasket in place. However, the EMI gasket is typically a thin metal and bending the tabs sometimes results in the tab breaking away from the rest of the EMI gasket. When a tab breaks, the EMI gasket must be replaced, which results in increased production costs. Additionally, these methods have a low fault-tolerance. Thus, if the EMI gasket is mis-aligned as its tabs are bent around the PCI bracket, the mounting bracket assembly will not function correctly and the entire assembly must be discarded.

Attaching PCBs to Electronic Systems

A PCB is typically attached to an electronic system by the process illustrated in FIG. 1. At step 100, the connectors of the PCB are lined up with the corresponding connectors of the electronic system and the mounting bracket assembly is lined up with a corresponding slot on the electronic system. At step 110, the PCB connectors and mounting bracket assembly are inserted into the corresponding connectors and slot on the electronic system. A PCB is “seated” when the connectors and assembly are correctly inserted into the electronic system. At step 120, a screw is used to fasten the mounting bracket assembly in place.

The screw of step 120 is typically screwed in facing the same direction as the connections from the PCB to the electronic system. Thus, if the PCB is not assembled correctly, fastening the PCB to the electronic system with the screw causes the end of the PCB which is opposite the fastening screw to rise. As the end of the PCB rises, the PCB becomes unseated from the electronic system. Thus, the connectors of the PCB are partially disconnected from the connectors of the electronic system and the PCB does not work properly.

FIG. 2 illustrates a PCB that becomes unseated as the PCB is screwed to the electronic system. The PCB (200) is attached to a mounting bracket (210). The mounting bracket is fastened to the electronic system (220) using a screw (230) which is screwed in the direction of direction arrow 1 (240). The mounting bracket and PCB are not aligned properly. Thus, as the screw is screwed into place, the far end (250) of the PCB moves in the direction of direction arrow 2 (260). This causes the connectors (270) for the PCB to become unseated from the connectors (280) for the electronic system.

Additionally, the slot for the screw used to fasten the mounting bracket assembly in place is typically not fully enclosed. Thus, it is possible for the mounting bracket assembly to slide completely free of the screw. This sometimes results in the PCB becoming unseated.

### SUMMARY OF THE INVENTION

The present invention provides a method and apparatus for fault-tolerant assembly of printed circuit board. In one embodiment of the present invention, an EMI gasket is configured to attach to a mounting bracket by snapping into place. Once attached, the EMI gasket is able to move some distance in every direction. Thus, this embodiment provides greater fault tolerance in PCB assembly.

In one embodiment, the slot for the screw used to affix the PCB to the system is elongated. In this embodiment, the elongation of the slot allows the PCB to move some distance in line with the PCB. Thus, the embodiment provides greater fault tolerance in PCB assembly and PCBs are no longer unseated by screwing the mounting bracket to the system. In another embodiment, the slot is enclosed. In this embodiment, the mounting bracket cannot slip free of the screw.

### BRIEF DESCRIPTION OF THE DRAWINGS

These and other features, aspects and advantages of the present invention will become better understood with regard to the following description, appended claims and accompanying drawings where:

FIG. 1 is a flow diagram of attaching a printed circuit board to an electronic system.

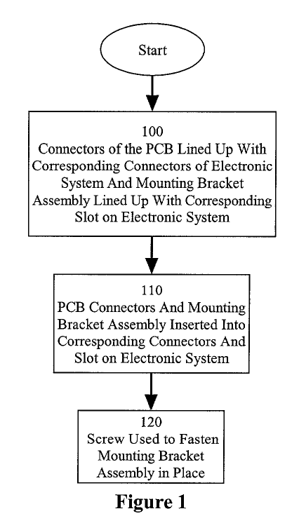

FIG. 2 is a block diagram of a PCB that becomes unseated as the PCB is screwed to the electronic system.

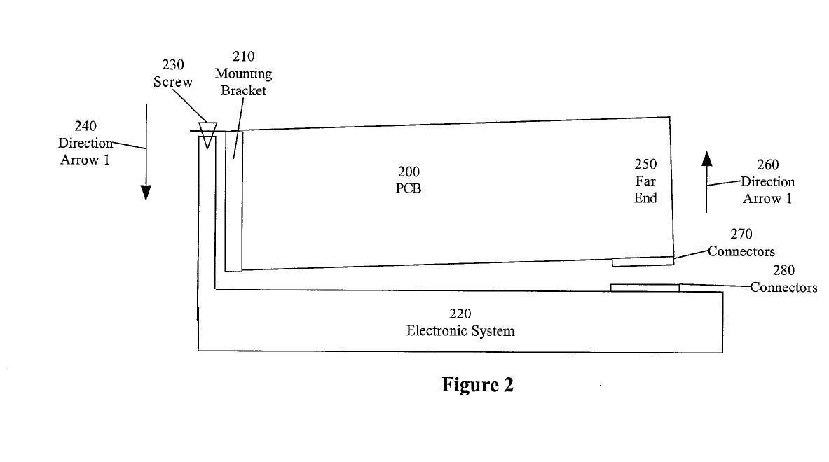

FIG. 3 is a flow diagram of the process of attaching an EMI gasket to a mounting bracket in accordance with one embodiment of the present invention.

FIG. 4 is a block diagram of a PCB that remains seated as the PCB is screwed to the electronic system in accordance with one embodiment of the present invention.

FIG. 5 is a block diagram of a PCB and electronic system in accordance with one embodiment of the present invention.

FIG. 6 is a block diagram of a mounting assembly in accordance with one embodiment of the present invention.

FIG. 7 is a block diagram of a PCB and electronic system in accordance with one embodiment of the present invention.

FIG. 8 is a block diagram of a mounting assembly in accordance with one embodiment of the present invention.

### DETAILED DESCRIPTION OF THE INVENTION

The invention is a method and apparatus for fault-tolerant assembly of printed circuit board. In the following description, numerous specific details are set forth to provide a more thorough description of embodiments of the invention. It is apparent, however, to one skilled in the art, that the invention may be practiced without these specific details. In other instances, well known features have not been described in detail so as not to obscure the invention.

Mounting Bracket Assembly

In one embodiment of the present invention, an EMI gasket is configured to attach to a mounting bracket by snapping into place. Once attached, the EMI gasket is able to move some distance in every direction. Thus, this embodiment provides greater fault tolerance in PCB assembly.

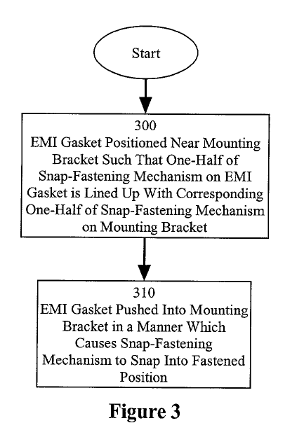

FIG. 3 illustrates the process of attaching an EMI gasket to a mounting bracket in accordance with one embodiment of the present invention. At step 300, the EMI gasket is positioned near the mounting bracket such that one-half of a snap-fastening mechanism on the EMI gasket is lined up with the corresponding one-half of the snap-fastening mechanism on the mounting bracket. At step 310, the EMI gasket is pushed into the mounting bracket in a manner which causes the snap-fastening mechanism to snap into a fastened position.

Affixing Screw Slot

In one embodiment, the slot for the screw used to affix the PCB to the system is elongated. In this embodiment, the elongation of the slot allows the PCB to move some distance in line with the PCB. If the mounting bracket and the PCB are slightly mis-aligned, screwing the mounting bracket into the system will cause the mounting bracket to move along the slot instead of raising the end of the PCB. Thus, the embodiment provides greater fault tolerance in PCB assembly and PCBs are no longer unseated by screwing the mounting bracket to the system.

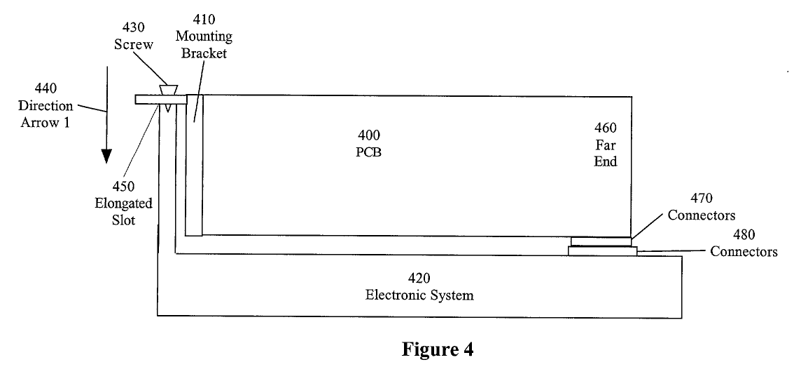

FIG. 4 illustrates a PCB that remains seated as the PCB is screwed to the electronic system in accordance with one embodiment of the present invention. The PCB (400) is attached to a mounting bracket (410). The mounting bracket is fastened to the electronic system (420) using a screw (430) which is screwed in the direction of direction arrow 1 (440). The screw fits through an elongated slot (450) on the mounting bracket. The mounting bracket and PCB are not aligned properly. However, as the screw is screwed into place, it is positioned in the slot so that the far end (460) of the PCB stays in place. Thus, the connectors (470) for the PCB do not become unseated from the connectors (480) for the electronic system.

In another embodiment, the slot is enclosed. In this embodiment, the mounting bracket cannot slip free of the screw. Thus, the PCB will not become unseated as a result of a loose screw problem.

Embodiments

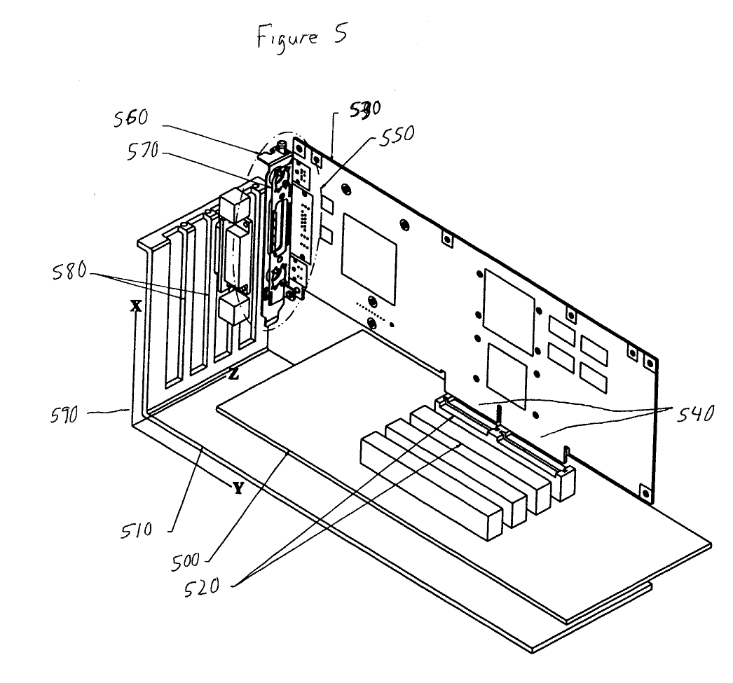

FIG. 5 illustrates a PCB and electronic system in accordance with one embodiment of the present invention. A motherboard (500) of the electronic system is enclosed in a chassis (510). The chassis serves to house the components of the electronic system and provide an electrical ground. The motherboard has connectors (520) where PCBs are able to connect to the electronic system. A PCB (530) is positioned with its connectors (540) above the connectors of the motherboard.

The mounting assembly (550) is comprised of a mounting bracket (560) and an EMI gasket (570). The mounting assembly is designed to affix the PCB to the chassis by sliding into a mounting slot (580) on the chassis. If the PCB is assembled correctly, the mounting assembly fit into the mounting slot and the PCB connectors fit into the motherboard connectors at the same time. The mounting assembly is designed to allow fault tolerance in the X, Y and Z directions indicated by the coordinate system (590) where X is in the direction the mounting assembly moves to slide into the mounting slots, Y is in the direction of the PCB which is perpendicular to X and Z is perpendicular to both X and Y.

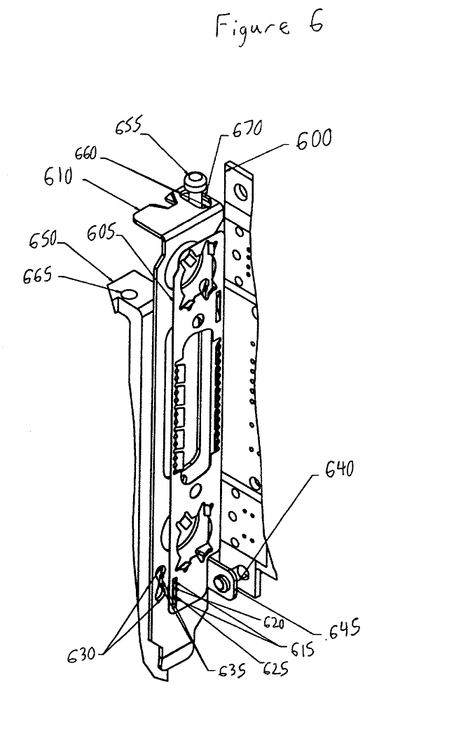

FIG. 6 illustrates a mounting assembly in accordance with one embodiment of the present invention. A PCB (600) is attached to an EMI gasket (605). The EMI gasket is designed to attach to a mounting bracket (610) by snapping into place. A snapping apparatus (615) on the EMI gasket is comprised of a slot (620) and a strip (625) wherein the strip connects to both ends of the slot. The strip is bent towards the mounting bracket.

A slot (630) on the mounting bracket is long enough for the strip of the EMI gasket to fit through it. However, the slot on the mounting bracket narrows at a mid-point (635). At the mid-point, the slot is slightly less wide than the strip on the EMI gasket. As pressure is applied to the EMI gasket towards the mounting bracket, the strip snaps past the narrow mid-point. Since the mid-point is still narrower than the slot, a significant force is required to snap the strip back through the narrow mid-point. Thus, the EMI gasket is held in place. Additionally, the configuration of the strip and the slot on the mounting bracket allows the EMI gasket to move slightly in all directions. Thus, the fault tolerance of the mounting assembly is increased.

Additionally, a screw (640) affixes a tab (645) on the mounting bracket to the PCB. The tab is the ground connection for the PCB because the mounting bracket is attached to the chassis (650) which serves as electrical ground for the electronic system. The mounting system is affixed to the chassis by a screw (655) which passes through an elongated slot (660) on the mounting bracket and a slot (665) on the chassis. The elongated slot allows fault tolerance in the PCB assembly by enabling the screw to be positioned anywhere in the slot. Thus, the end of the PCB does not rise as the screw is screwed in and the PCB does not becomes unseated. The elongated slot is completely enclosed by a strip (670) of the mounting bracket. The enclosed slot prevents the screw from coming loose from the mounting assembly. Thus, the PCB does not become unseated because of a loose screw.

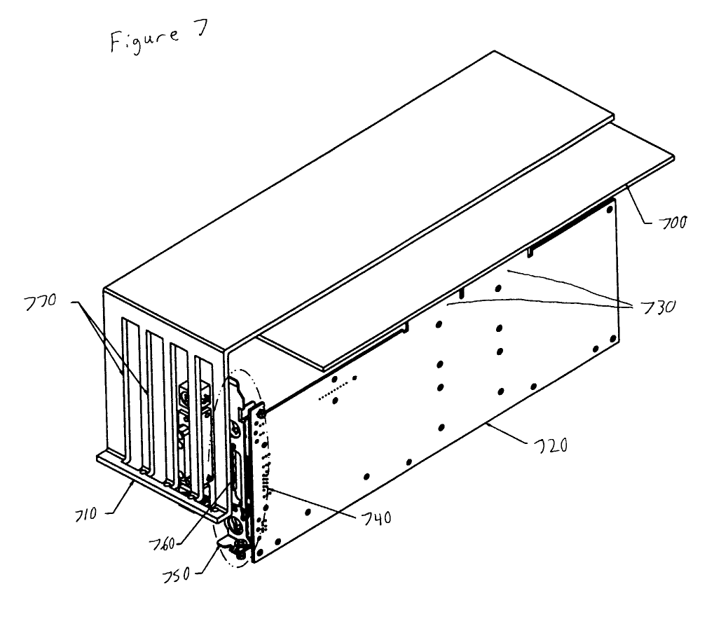

FIG. 7 illustrates a bottom view of a PCB and electronic system in accordance with one embodiment of the present invention. A motherboard (700) of the electronic system is enclosed in a chassis (710). The chassis serves to house the components of the electronic system and provide an electrical ground. The motherboard has connectors on the unseen surface where PCBs are able to connect to the electronic system. A PCB (720) is positioned with its connectors (730) below the connectors of the motherboard.

The mounting assembly (740) is comprised of a mounting bracket (750) and an EMI gasket (760). The mounting assembly is designed to affix the PCB to the chassis by sliding into a mounting slot (770) on the chassis. If the PCB is assembled correctly, the mounting assembly fit into the mounting slot and the PCB connectors fit into the motherboard connectors at the same time. The mounting assembly is designed to allow fault tolerance in all directions.

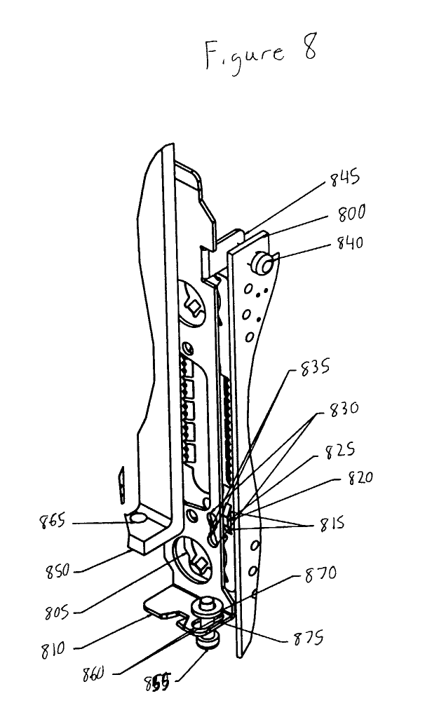

FIG. 8 illustrates a bottom view of a mounting assembly in accordance with one embodiment of the present invention. A PCB (800) is attached to an EMI gasket (805). The EMI gasket is designed to attach to a mounting bracket (810) by snapping into place. A snapping apparatus (815) on the EMI gasket is comprised of a slot (820) and a strip (825) wherein the strip connects to both ends of the slot. The strip is bent towards the mounting bracket.

A slot (830) on the mounting bracket is long enough for the strip of the EMI gasket to fit through it. However, the slot on the mounting bracket narrows at a mid-point (835). At the mid-point, the slot is slightly less wide than the strip on the EMI gasket. As pressure is applied to the EMI gasket towards the mounting bracket, the strip snaps past the narrow mid-point. Since the mid-point is still narrower than the slot, a significant force is required to snap the strip back through the narrow mid-point. Thus, the EMI gasket is held in place. Additionally, the configuration of the strip and the slot on the mounting bracket allows the EMI gasket to move slightly in all directions. Thus, the fault tolerance of the mounting assembly is increased.

Additionally, a screw (840) affixes a tab (845) on the mounting bracket to the PCB. The tab is the ground connection for the PCB because the mounting bracket is attached to the chassis (850) which serves as electrical ground for the electronic system. The mounting system is affixed to the chassis by a screw (855) which passes through an elongated slot (860) on the mounting bracket and a slot (865) on the chassis. The screw is held in place by a washer (870). The elongated slot allows fault tolerance in the PCB assembly by enabling the screw to be positioned anywhere in the slot. Thus, the end of the PCB does not rise as the screw is screwed in and the PCB does not becomes unseated. The elongated slot is completely enclosed by a strip (875) of the mounting bracket. The enclosed slot prevents the screw from coming loose from the mounting assembly. Thus, the PCB does not become unseated because of a loose screw.

Thus, a method and apparatus for fault-tolerant assembly of printed circuit board is described in conjunction with one or more specific embodiments. The invention is defined by the following claims and their full scope and equivalents.

1. A method of assembling a printed circuit board comprising:
attaching an electromagnetic interference gasket to a mounting bracket wherein said step of attaching is accomplished by a snapping mechanism.

2. The method of claim 1 wherein said step of attaching comprises:
providing a snapping slot on said mounting bracket wherein said snapping slot narrows at a mid-point; and
providing a snapping strip on said electromagnetic interference gasket wherein said snapping strip is wider than said mid-point; and
applying a force wherein said force is sufficient to snap said snapping strip past said mid-point of said snapping slot.

3. The method of claim 1 wherein further comprising:
attaching said mounting bracket to said printed circuit board by screwing a tab on said mounting bracket to said printed circuit board.

4. The method of claim 3 wherein said tab is used as an electrical ground voltage for said printed circuit board.

5. A method of assembling a printed circuit board comprising:
providing an elongated slot on a mounting bracket configured to allow a screw to pass through said slot in a plurality of locations wherein said screw is used to affix said mounting bracket to a chassis of an electronic system.

6. The method of claim 5 wherein said slot is completely enclosed.

7. A printed circuit board comprising:
a snapping mechanism configured to attach an electromagnetic interference gasket to a mounting bracket.

8. The printed circuit board of claim 7 wherein said snapping mechanism comprises:
a snapping slot on said mounting bracket wherein said snapping slot narrows at a mid-point; and
a snapping strip on said electromagnetic interference gasket wherein said snapping strip is wider than said mid-point and wherein said snapping strip is configured to snap past said mid-point of said snapping slot when a sufficient force is applied.

9. The printed circuit board of claim 7 wherein mounting bracket is configured to attach to said printed circuit board by screwing a tab on said mounting bracket to said printed circuit board.

10. The printed circuit board of claim 9 wherein said tab is used as an electrical ground voltage for said printed circuit board.

11. A printed circuit board comprising:
an elongated slot on a mounting bracket configured to allow a screw to pass through said slot in a plurality of locations wherein said screw is used to affix said mounting bracket to a chassis of an electronic system.

12. The printed circuit board of claim 11 wherein said slot is completely enclosed.
